(19) United States
(12) Patent Application Publication
(10) Pub. No.: US 2020/0075455 A1
(43) Pub. Date: Mar. 5, 2020

(54) Circuit Cooled on Two Sides

(71) Applicant: CeramTec GmbH, Plochingen (DE)

(72) Inventors: Roland DILSCH, Thierstein (DE); Harald KRESS, Langenzenn (DE)

(21) Appl. No.: 16/603,083

(22) PCT Filed: Mar. 28, 2018
(86) PCT No.: PCT/EP2018/057953

§ 371 Date: Oct. 4, 2019

(30) Foreign Application Priority Data
Apr. 6, 2017 (DE) 10 2017 205 906.0

(51) Int. Cl. H01L 23/373; H01L 23/367; H01L 23/473; H01L 23/467; H01L 23/00

(52) U.S. Cl. CPC H01L 23/3735; H01L 23/3677; H01L 23/473; H01L 23/467; H01L 2224/33; H01L 24/73; H01L 2224/73265; H01L 2224/73215; H01L 24/33

(57) ABSTRACT

A component (9) includes a first ceramic substrate (1), a ceramic fin cooler or a ceramic cooler through which liquid flows, having an upper face (1b) and a lower face (1a). A metallization (2) is applied to the upper face (1b), on which metallization a circuit (4) is mounted by its lower face. The circuit (4) of the component (9) is cooled on both sides by elements having high thermal conductivity and at the same time high electrical conductivity and thus the efficiency of the assembly is increased. A ceramic electrical/thermal conduction substrate (6) is attached by its lower face to the upper face of the circuit by a connection, and a second ceramic substrate (8) is arranged on the upper face of the electrical/thermal conduction substrate (6) via a metallization (7). The substrate (8) contains metal-filled thermal-electrical vias (11) and/or cooling channels to guide a coolant.

The invention relates to a component consisting of a first ceramic substrate, a ceramic fin cooler or a liquid-operated ceramic cooler or a ceramic heat sink (air- or liquid-cooled) comprising an upper face and lower face, a metallization being applied to the upper face, to which metallization a circuit made of a semi-conductor material is attached by the lower face thereof via a connecting means.

It is known that ceramic substrates made of Al₂O₃, AlN or Si₃N₄ carry an at least single-sided metallization (DCB-Cu, thick-film Cu, Ag, W—Ni—Au), to which in turn a circuit is attached in a manner secured by pressure, solder, sintered silver, silver glue or the like.

Additional metallization surfaces may be provided on the second side of the substrate, to which surfaces, for example, a heat sink made of aluminum or the like is glued or soldered. The circuits are thus connected to an electrically insulating heat sink on at most one side. The upper free face of the circuit is at most gas cooled. A circuit is also generally understood to mean a chip or a transistor.

The object of the invention is that of improving a component according to the preamble of claim 1 such that the circuit is cooled on both sides, i.e. cooled both on the lower face and on the upper face thereof. The double-sided cooling of the circuits by elements with high thermal conductivity and simultaneously high electrical conductivity is intended to increase the efficiency of the assembly. Furthermore, it is intended to be ensured that the component retains its full functionality when heated or during overall temperature changes and does not fail.

According to the invention this object is achieved by a component having the features of claim 1. The circuit is cooled on both sides, i.e. both on the upper face thereof and on the lower face thereof, by a connecting means being applied to the upper face of the circuit, to which connecting means a ceramic current/heat-conducting substrate is applied by the lower face thereof, and a second ceramic substrate being arranged on the upper face of the current/heat-conducting substrate via a metallization, the ceramic current/heat-conducting substrate containing metal-filled thermal-electrical plated through-holes (vias) for cooling, the upper face and lower face of the current/heat-conducting substrate (6) being electrically interconnected in both cooling variants. The double-sided cooling of the circuit by elements with high thermal conductivity and simultaneously high electrical conductivity increases the efficiency of the circuit assembly.

The metal in the vias of the ceramic current/heat-conducting substrate rests on both the metallization of the second substrate and on the connecting means which is located on the circuit.

Preferably, the ceramic of the current/heat-conducting substrate has a coefficient of expansion which is adapted to the coefficient of expansion of the semiconductor material of the circuit. As a result, the component retains its full functionality when heated or during overall temperature changes and does not fail.

The coefficients of expansion of the current/heat-conducting substrate and of the circuit differ from one another by a maximum of 3 ppm. Preferably, the current/heat-conducting substrate is a cuboid or a flat substrate.

The circuit is preferably a silicon circuit, SiC circuit or a GaN circuit, such as a diode or a transistor.

The metallizations are preferably made of DCB-Cu, AMB-Cu, thick-film Cu, Ag or W—Ni—Au and/or are metallizations that are sintered to the ceramic substrate. Sintered metallizations are intimately bonded to the ceramic material and thus have excellent heat transfer from the circuit into the ceramic material.

The connecting means is preferably a solder, sintered silver or thermally conductive adhesive.

In one embodiment according to the invention, the plated through-holes consist of Cu or Ag and the substrates consist of aluminum nitride, aluminum oxide or silicon nitride. These ceramics have a high thermal conductivity.

In one embodiment, cooling elements, such as fins or the like, are arranged on the lower face of the first ceramic substrate, or the substrate itself is designed as an air-operated or liquid-operated heat sink.

With the aid of the ceramic current/heat-conducting substrate, comprising metal-filled vias, which contacts the free upper face of the circuit via the connecting means, improved double-sided heat dissipation can take place. This current/heat-conducting substrate contains metal-filled thermal-electrical plated through-holes (vias) filled with, for example, Cu or Ag. If aluminum nitride is selected as a substrate material, the coefficient of expansion thereof of approximately 4.7 ppm/K is close to the silicon of the chip.

These via ceramic materials (current/heat-conducting substrate) can be connected to a second ceramic substrate both on the side of the circuit as well as on the other side of the metallized ceramic substrate via solder, silver paste or silver sintered film or, when burning in the copper paste, directly to the copper layer of the metallized upper face substrate.

To further increase the heat dissipation, it is also possible to use liquid-operated ceramic coolers or those with ceramic fins instead of the ceramic current/heat-conducting substrates.

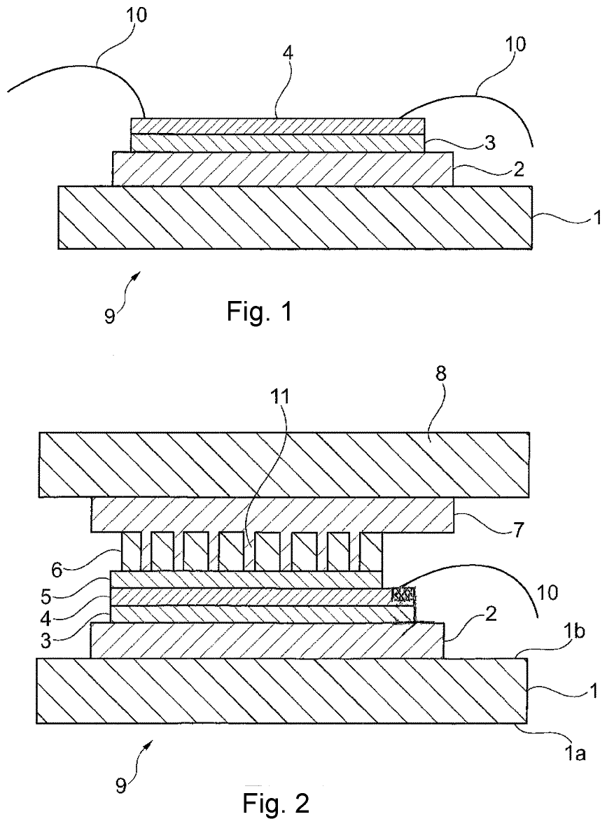

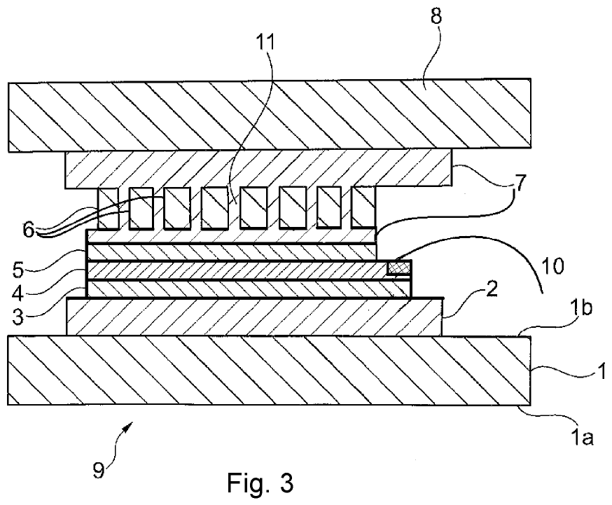

The figures show the prior art (FIG. 1) and a component according to the invention (FIG. 2) and, by way of example, another component according to the invention comprising an additional layer of the metallization 7 (FIG. 3).

FIG. 1 shows a component 9 consisting of a first ceramic substrate 1 comprising an upper face 1b and lower face 1a, a metallization 2 being applied to the upper face 1b, to which metallization a circuit 4 made of a semi-conductor material is attached by the lower face thereof via a connecting means 3.

FIG. 2 shows a component 9 according to the prior art. The component consists of a first ceramic substrate 1 comprising an upper face 1b and lower face 1a, a metallization 2 being applied to the upper face 1b, to which metallization a circuit 4 is attached by the lower face thereof via a connecting means 3. According to the invention, a ceramic current/heat-conducting substrate 6 is applied by the lower face thereof to the circuit 4 or to the upper face thereof via a connecting means 5, and a second ceramic substrate 8 is arranged on the current/heat-conducting substrate 6 via a metallization 7, the ceramic current/heat-conducting substrate 6 containing metal-filled thermal-electrical plated through-holes (vias) 11 and/or cooling channels for conducting a coolant.

The ceramic substrates 1, 8 are preferably planar and consist of aluminum oxide, silicon nitride or preferably aluminum nitride, which has a very high thermal conductivity.

The metallizations preferably consist of DCB-Cu, AMB-Cu, thick-film Cu, Ag or W—Ni—Au and/or are sintered to the ceramic substrate 1, 8.

The circuit 4 is a diode or a transistor in the embodiment shown.

The connecting means 3, 5 are preferably solder, sintered silver or silver glue.

The plated through-holes 11 consist of Cu or Ag, for example.

Cooling elements (not shown in FIG. 2) are preferably arranged on the lower face 1a of the first ceramic substrate 1. The cooling elements 1 and 8 may contain fins for air cooling. However, they may also be liquid-controlled coolers.

The ceramic current/heat-conducting substrate 6 is used to dissipate the waste heat of the circuit 4 into the ceramic substrate 8 and can also be used for electrical coupling of the circuit 4 to the metallization 7. The current/heat-conducting substrate 6 is also made of aluminum oxide, silicon nitride or preferably aluminum nitride. The waste heat is transported and an electrical connection is established through the metal-filled thermal-electrical plated through-holes (vias) 11 of said substrate. The plated through-holes (vias) 11 preferably extend at right angles to the surface of the current/heat-conducting substrate 6.

Electrical connections are denoted by reference sign 10.

FIG. 3 shows that a further layer of the metallization 7 can be applied between the connecting means 5 and the ceramic current/heat-conducting substrate 6. This layer is preferably materially connected, via the metal-filled thermal-electrical plated through-holes (vias), to the metallization layer 7 which is arranged between the current/heat-conducting substrate 6 and a second ceramic substrate 8.

1. Component consisting of a first ceramic substrate, a ceramic fin cooler or a liquid-operated ceramic cooler comprising an upper face and lower face, a metallization being applied to the upper face, to which metallization a circuit made of a semi-conductor material is attached by the lower face thereof via a connecting means, wherein
a. a connecting means is applied to the upper face of the circuit, to which connecting means a ceramic current/heat-conducting substrate is applied by the lower face thereof, and a second ceramic substrate, a ceramic fin cooler or a liquid-operated ceramic cooler is arranged on the upper face of the current/heat-conducting substrate via a metallization,
b. the ceramic current/heat-conducting substrate containing metal-filled thermal-electrical plated through-holes (vias) for cooling the semiconductor,
c. the upper face and lower face of the current/heat-conducting substrate being electrically interconnected in both cooling variants.

2. Component according to claim 1, wherein the ceramic material of the current/heat-conducting substrate has a coefficient of expansion adapted to a coefficient of expansion of the semiconductor material of the circuit.

3. Component according to claim 2, wherein the coefficient of expansion of the current/heat-conducting substrate differs by at most 3 ppm/K from the coefficient of expansion of the semiconductor material of the circuit.

4. Component according to claim 1, wherein the circuit is a silicon circuit, SiC circuit, or a GaN circuit, for example a diode or a transistor.

5. Component according to claim 1, wherein all metallizations consist of DCB-Cu, AMB-Cu, thick-film Cu, Ag or W—Ni—Au and/or are metallizations that are sintered to the ceramic substrate.

6. Component according to claim 1, wherein the connecting means are solder, sintered silver or silver glue.

7. Component according to claim 1, wherein the plated through-holes consist of Cu or Ag and the substrates consist of aluminum nitride.

8. Component according to claim 1, wherein cooling elements are arranged on the lower face of the first ceramic substrate.

9. Component according to claim 1, wherein the current/heat-conducting substrate is a cuboid or a flat substrate.
